(19) United States
(12) Patent Application Publication
(10) Pub. No.: US 2025/0126895 A1
(43) Pub. Date: Apr. 17, 2025

(54) ARRAY SUBSTRATE AND DISPLAY DEVICE

(71) Applicant: KunShan Go-Visionox Opto-Electronics Co., Ltd, Kunshan (CN)

(72) Inventors: Xu QIN, Kunshan (CN); Tingting ZHANG, Kunshan (CN); Chuanzhi XU, Kunshan (CN); Mengyu CHEN, Kunshan (CN)

(73) Assignee: KunShan Go-Visionox Opto-Electronics Co., Ltd, Kunshan (CN)

(21) Appl. No.: 18/897,138

(22) Filed: Sep. 26, 2024

(30) Foreign Application Priority Data
Oct. 16, 2023 (CN) 202311338814.1

(51) Int. Cl. H01L 27/12

(52) U.S. Cl. CPC H10D 86/60; H10D 86/443

(57) ABSTRACT

An array substrate and a display device. The array substrate includes a display area and a non-display area at least partially surrounding the display area. The array substrate includes a substrate, at least one first signal line, at least one dam, and an encapsulation layer. The at least one first signal line is disposed on one side of the substrate. At least part of a first signal line is first signal lines are disposed in the curved area of the non-display area. The at least one dam is disposed in the non-display area and disposed on a side of the at least one first signal line away from the substrate. The orthographic projection of the encapsulation layer on the substrate covers the orthographic projection of the first signal line on the substrate.

### CROSS-REFERENCE TO RELATED APPLICATION(S)

This application claims priority to Chinese Patent Application No. 202311338814.1 filed Oct. 16, 2023, the disclosure of which is incorporated herein by reference in its entirety.

### TECHNICAL FIELD

Embodiments of the present disclosure relate to the field of display technology, particularly an array substrate and a display device.

### BACKGROUND

As the display technology advances, people's demands for display panels are becoming increasingly higher. Dams in the curved area of the lower bezel of an existing display device are improperly disposed and prone to wire breakage and thus affect the display effect of the display device.

### SUMMARY

Embodiments of the present disclosure provide an array substrate and a display device to solve the problem that dams in the curved area of the lower bezel of the array substrate are disposed improperly and prone to wire breakage and thus affect the display effect of the display device.

To solve this problem, the present disclosure uses the following solution.

Embodiments of the present disclosure provide an array substrate.

The array substrate includes a display area and a non-display area at least partially surrounding the display area. The array substrate includes a substrate, at least one first signal line, at least one dam, and an encapsulation layer. The at least one first signal line is disposed on one side of the substrate. For each of the at least one first signal line, at least part of a first signal line is located in the curved area of the non-display area. The at least one dam is disposed in the non-display area and on a side of the at least one first signal line away from the substrate. The orthographic projection of the encapsulation layer on the substrate completely covers the orthographic projection of the first signal line on the substrate.

Optionally, the at least one dam includes at least a first dam located on the side of the non-display area away from the display area, the orthographic projection of the first dam on the substrate, at least partially covers the orthographic projection of the first signal line on the substrate.

Preferably, the first signal line has a first boundary away from the display area, and the orthographic projection of the first dam on the substrate, covers the orthographic projection of the first boundary on the substrate.

Optionally, the array substrate also includes a second signal line. The second signal line is located on the side of the at least one first signal line away from the substrate.

The orthographic projection of the second signal line on the substrate at least partially covers the orthographic projection of the first signal line on the substrate.

Preferably, the second signal line is configured to transmit a fixed potential.

Optionally, the first dam is located on the side of the non-display area facing away from the display area, the orthographic projection of the first dam on the substrate, at least partially covers the orthographic projection of the second signal line on the substrate.

Preferably, the second signal line has a second boundary away from the display area, the orthographic projection of the first dam on the substrate, completely covers an orthographic projection of the second boundary on the substrate.

Preferably, the distance between the second boundary and a third boundary of the first dam, is greater than or equal to 5 μm.

Optionally, the first dam includes a first insulating layer. The first insulating layer is located on the side of the second signal line away from the substrate.

The first insulating layer covers at least a second boundary of the second signal line away from the display area.

Preferably, the first insulating layer includes an organic material.

Preferably, the at least one dam includes at least a second dam located on a side of the non-display area closer to the display area than the first dam, and the height of the first dam is greater than the height of the second dam.

Optionally, the array substrate also includes at least one multiplexer disposed in the non-display area. The at least one multiplexer is connected to the at least one first signal line. The at least one multiplexer is configured to convert at least two of the at least one first signal line located in the display area into a single first signal line of the at least one first signal line located in the non-display area.

Preferably, the port number ratio of each of the at least one multiplexer includes 1:9 or 1:12.

Optionally, the array substrate also includes a first conductive layer disposed on one side of the substrate; and a second conductive layer disposed on the side of the first conductive layer away from the substrate.

The first signal line is disposed in the first conductive layer and the second conductive layer.

Preferably, the array substrate also includes a third conductive layer disposed on the side of the second conductive layer away from the substrate. The at least one dam is disposed between the third conductive layer and the encapsulation layer. The second signal line is located in the third conductive layer.

Optionally, the distance range from the first dam to a fourth boundary of the encapsulation layer includes 5 μm to 10 μm.

Optionally, the encapsulation layer located in the non-display area includes a first layer and a second layer which are stacked.

Preferably, the first layer and the second layer include an inorganic material.

Optionally, the array substrate also includes a touch line located on the side of the encapsulation layer away from the substrate and configured to transmit a touch signal.

Embodiments of the present disclosure also provide a display device. The display device includes the array substrate of any previous embodiment.

In the array substrate and display device of embodiments of the present disclosure, the orthographic projection of the encapsulation layer on the substrate completely covers the orthographic projection of the first signal line on the substrate so that the encapsulation layer covers all of the side of the first signal line away from the substrate. This ensures that the non-display area is relatively flat, facilitating the arrangement of signal lines such as the touch layer on the side of the encapsulation layer away from the substrate. This improves the yield of the touch line of the touch layer, thereby improving the display effect of the display device.

### BRIEF DESCRIPTION OF DRAWINGS

To illustrate solutions in embodiments of the present application more clearly, the drawings used in description of the embodiments of the present disclosure are described briefly hereinafter. Apparently, the drawings described hereinafter only illustrate part of embodiments of the present application, and those skilled in the art may obtain other drawings based on the contents and drawings described in the embodiments of the present disclosure on the premise that no creative work is done.

FIG. 1 is a diagram illustrating the structure of an array substrate according to embodiments of the present disclosure.

FIG. 2 is an enlarged view of region D of the array substrate of FIG. 1 according to embodiments of the present disclosure.

FIG. 3 is a section view taken along direction AA′ of the array substrate of FIG. 1 according to embodiments of the present disclosure.

FIG. 4 is another section view taken along direction AA′ of the array substrate of FIG. 1 according to embodiments of the present disclosure.

FIG. 5 is another section view taken along direction AA′ of the array substrate of FIG. 1 according to embodiments of the present disclosure.

FIG. 6 is another section view taken along direction AA′ of the array substrate of FIG. 1 according to embodiments of the present disclosure.

FIG. 7 is another section view taken along direction AA′ of the array substrate of FIG. 1 according to embodiments of the present disclosure.

FIG. 8 is another section view taken along direction AA′ of the array substrate of FIG. 1 according to embodiments of the present disclosure.

### DETAILED DESCRIPTION

The present disclosure is further described in detail below in conjunction with the drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

In view of this problem, this embodiment provides the following solution:

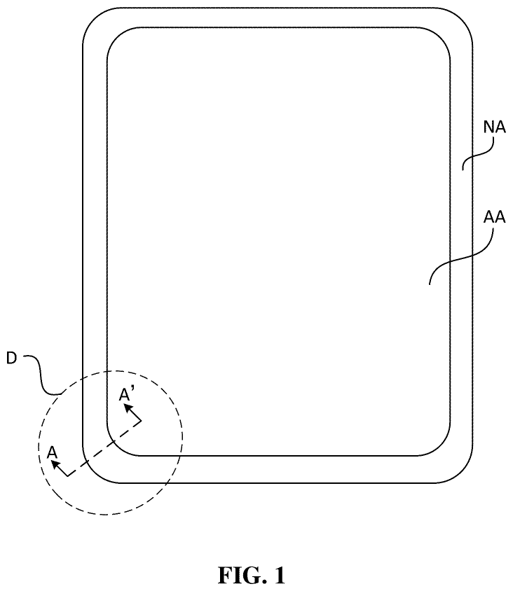

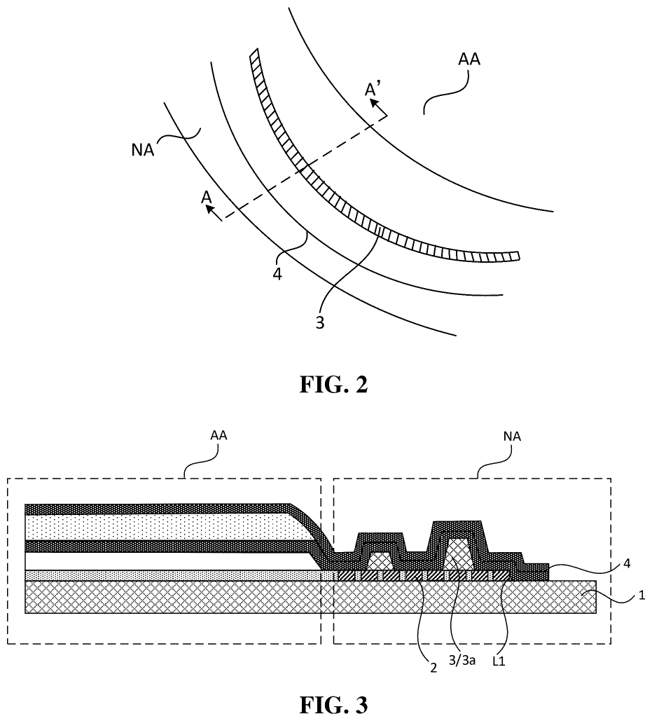

FIG. 1 is a structural diagram of an array substrate according to an embodiment of the present disclosure. FIG. 2 is an enlarged view of region D of the array substrate of FIG. 1 according to embodiments of the present disclosure. FIG. 3 is a section view taken along direction AA′ of the array substrate of FIG. 1 according to embodiments of the present disclosure. Referring to FIG. 1 to FIG. 3, the array substrate of embodiments of the present disclosure includes a display area AA and a non-display area NA at least partially surrounding the display area AA. The array substrate includes a substrate 1, at least one first signal line 2, at least one dam 3, and an encapsulation layer 4. At least part of the at least one first signal line 2 is disposed in the non-display area NA. The at least one dam 3 is located in the non-display area NA and on a side of the at least one first signal line 2 away from the substrate 1. The orthographic projection of the encapsulation layer 4 on the substrate 1 completely covers the orthographic projection of the first signal line 2 on the substrate 1.

Specifically, the display device includes a terminal such as a mobile phone and a wearable device. The array substrate generally uses thin-film encapsulation. To reduce costs, the touch layer is disposed on the thin-film encapsulation layer 4. The touch layer is connected to a control chip by using the lower bezel of the array substrate. The touch layer and the array display layer share the same control chip.

The first signal line 2 includes a fan-out wire. Dams 3 of an existing array substrate typically follow the boundary of the display area AA. However, the first signal line 2 extends from the side bezel of the array substrate to the lower bezel of the array substrate. In the direction from the upper bezel to the lower bezel, the number of the first signal lines 2 gradually increases. At the lower left bezel and the lower right bezel of the array substrate, there are many first signal lines 2, but the distance from the dams 3 to the display area AA is constant. This causes the first signal line 2 to cross the most outer dam 3. The distance from the boundary of the encapsulation layer 4 to the most outer dam 3 is a constant preset distance. As a result, the boundary of first signal line 2 away from the display area AA is beyond the coverage of the encapsulation layer 4 Because the side of the encapsulation layer 4 away from the substrate 1 is relatively flat, the touch line of the touch layer is relatively flat. However, for a first signal line 2 beyond the encapsulation layer 4, the side of the first signal line 2 away from the substrate 1 is not flat. Because many first signal lines 2 exist, the first signal lines 2 may be disposed in multiple layers so that there are relatively many pits on the side of the first signal line 2 away from the substrate 1. The touch line of the touch layer is prone to wire breakage at a pit on the side of the first signal line 2 away from the substrate 1, affecting the display effect of the display device.

The orthographic projection of the first signal line 2 on the substrate 1 is completely covered by the orthographic projection of the encapsulation layer 4 on the substrate 1 so that in the non-display area NA of the array substrate, the encapsulation layer 4 covers all of the side of the first signal line 2 away from the substrate 1. The encapsulation layer 4 includes at least an inorganic layer, an organic layer, and an inorganic layer which are stacked in the display area AA.

The encapsulation layer 4 includes stacked inorganic layers in the non-display area NA so that the side of the encapsulation layer 4 away from the substrate 1 is quite flat, reducing pits caused by the first signal line 2. When the touch line of the touch layer is disposed on the side of the encapsulation layer 4 away from the substrate 1, a wire breakage risk does not easily occur, thereby improving the yield of the touch line of the touch layer.

The lower left bezel or the lower right bezel of the array substrate is bigger than the left bezel and the right bezel of the array substrate. The distance between the dam 3 and the boundary of the encapsulation layer 4 is relatively constant. Thus, in the non-display area NA with a relatively large number of first signal lines 2, the dams 3 may follow the boundary of the encapsulation layer 4 so that at the lower left bezel or the lower right bezel, the distance between the dam 3 and the boundary of the display area AA is relatively large.

In the array substrate of embodiments of the present disclosure, the orthographic projection of the encapsulation layer 4 on the substrate 1 completely covers the orthographic projection of the first signal line on the substrate 1 so that the encapsulation layer 4 covers all of the side of the first signal line away from the substrate 1. This ensures that the non-display area NA is relatively flat, facilitating the arrangement of signal lines such as the touch layer on the side of the encapsulation layer 4 away from the substrate 1. This improves the yield of the touch line TP of the touch layer, thereby improving the display effect of the display device.

FIG. 1 and FIG. 2 show no first signal line 2. FIG. 3 shows that the second signal line 2 is located in the same layer. This is not limited here.

Optionally, based on the previous embodiments, referring to FIG. 3, for the dam 3 on the side of the non-display area NA away from the display area AA, the orthographic projection of the dam 3 on the substrate 1 at least partially covers the orthographic projection of the first signal line 2 on the substrate 1.

Specifically, the dam 3 on the side of the non-display area NA away from the display area AA is the outer dam 3a. This arrangement makes the first signal line 2 have a large coverage area, increasing the wiring space of the first signal line 2. This arrangement also makes the dam 3 on the side of the first signal line 2 away from the substrate 1 better protect the first signal line 2, better improving the display effect of the array substrate.

Optionally, FIG. 4 is another section view taken along direction AA′ of the array substrate of FIG. 1 according to embodiments of the present disclosure. Optionally, based on the previous embodiments, referring to FIG. 4, the dams 3 include at least a first dam 31 located on the side of the non-display area NA away from the display area AA, the first signal line 2 has a first boundary away from the display area AA, the orthographic projection of the first dam 31 on the substrate 1 covers the orthographic projection of the first boundary on the substrate 1.

Specifically, since the distance from the boundary of the encapsulation layer 4 away from the display area AA to the dam 3 is relatively constant, the orthographic projection of the dam 3 on the substrate 1 is disposed to cover the orthographic projection of the first boundary on the substrate 1. This arrangement makes the first boundary L1 of the first signal line 2 located within the boundary of the outer dam 3a, enhancing the ability of the dam 3 to protect the first signal line 2, better preventing the first signal line 2 from affecting the wiring of the touch line TP of the touch layer, and better improving the display effect of the display device.

In an optional embodiment, the distance from the first dam 31 to the first boundary L1 of the first signal line 2 may be set to a preset value, for example, a constant value. That is, the extension direction of the first dam 31 follows the first boundary L1 of the first signal line 2.

In another optional embodiment, the distance from the first dam 31 to the boundary of the non-display area NA away from the display area AA of the display device may be a constant value. That is, the direction of the first dam 31 follows the boundary of the non-display area NA away from the display area AA of the display device. The extension direction of the dam 3 may be disposed according to the requirements and is not limited here.

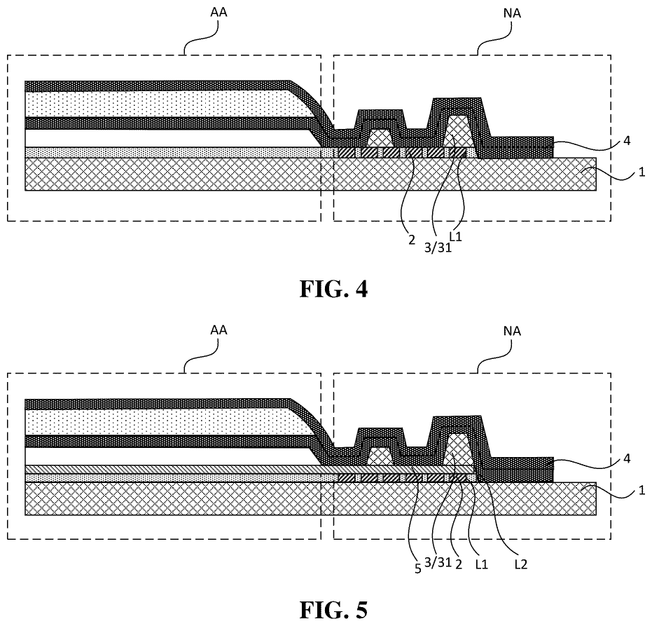

FIG. 5 is another section view taken along direction AA′ of the array substrate of FIG. 1 according to embodiments of the present disclosure. Optionally, based on the previous embodiments, referring to FIG. 5, the array substrate also includes a second signal line 5. The second signal line 5 is located on the side of the at least one first signal line 2 away from the substrate 1. The orthographic projection of the second signal line 5 on the substrate 1 at least partially covers the orthographic projection of the first signal line 2 on the substrate 1. Preferably, the second signal line 5 is disposed to transmit a fixed potential.

Specifically, the second signal line 5 is disposed on the side of the first signal line 2 away from the substrate 1 so that the second signal line 5 can better protect the first signal line 2. The second signal line 5 can transmit a fixed potential. For example, the second signal line 5 may be a power signal line for transmitting a cathode potential signal to the array substrate. Since there are many first signal lines 2, and the signals transmitted by the first signal lines 2 may include data signals, the orthographic projection of the second signal line 5 on the substrate 1 is disposed to at least partially cover the orthographic projection of the first signal line 2 on the substrate 1, allowing the second signal line 5 to better shield against static electricity, improving the capability of the first signal line 2 to shield against static electricity, and enhancing the display effect of the display device.

Optionally, based on the previous embodiments, referring to FIG. 5, the first dam 31 is located on the side of the non-display area NA away from the display area AA, the orthographic projection of the first dam 31 on the substrate 1, at least partially covers the orthographic projection of the second signal line 5 on the substrate.

Specifically, this allows the second signal line 5 to better shield against static signals, thereby improving the anti-static capability of the first signal line 2, and enhancing the display effect of the display device.

Optionally, based on the previous embodiments, referring to FIG. 5, the second signal line 5 has a second boundary L2 away from the display area AA, the orthographic projection of the first dam 31 on the substrate 1, completely covers the orthographic projection of the second boundary L2 on the substrate 1.

Specifically, the second signal line 5 may be made of a metal, for example, titanium, aluminum, or titanium-aluminum titanium. The arrangement in which the orthographic projection of the dam 3 on the substrate 1 completely covers the orthographic projection of the second boundary L2 on the substrate 1 makes the outer dam 3a better cover and protect the second signal line 5, better improving the display effect of the display device.

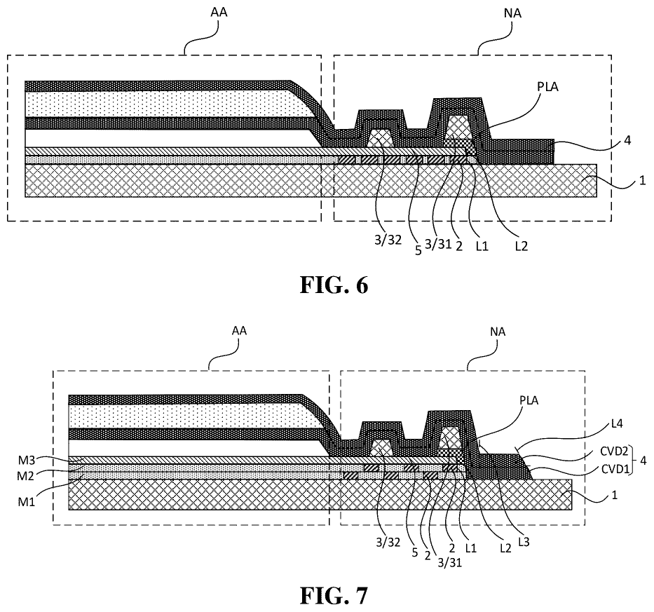

FIG. 6 is another section view taken along direction AA′ of the array substrate of FIG. 1 according to embodiments of the present disclosure. Optionally, based on the previous embodiments, referring to FIG. 6 and FIG. 7, the first dam 31 is located on the side of the non-display area NA away from the display area AA, the second signal line 5 has a second boundary L2 away from the display area AA, the distance between the second boundary L2 and a third boundary L3 of the first dam 31, is greater than or equal to 5 μm.

Specifically, the second boundary L2 of the second signal line 5 is located on the side of the outer dam 3a facing the display area AA. Because the film of the dam 3 is relatively thick, the arrangement in which the distance between the second boundary L2 and the third boundary L3 is greater than or equal to 5 μm makes the outer dam 3a better protect the second signal line 5. This arrangement can also better protect the first signal line 2 and improve the capability of the first signal line 2 to shield against static electricity. Moreover, this arrangement makes the second signal line 5 wider, thereby reducing the line resistance of the second signal line 5, lowering the load voltage drop of the second signal line 5, and better improving the display effect of the display device.

Optionally, based on the previous embodiments, referring to FIG. 6, the first dam 31 includes a first insulating layer PLA. The first insulating layer PLA is located on the side of the second signal line 5 away from the substrate 1. The first insulating layer PLA covers at least a second boundary L2 of the second signal line 5 away from the display area AA. Optionally, the first insulating layer PLA includes an organic material.

Specifically, the first insulating layer PLA is located on the side of the second signal line 5 away from the substrate 1 and covers at least a second boundary L2 of the second signal line 5 away from the display area AA so that the section of the second boundary L2 of the second signal line 5 is covered by the first insulating layer PLA. This arrangement improves the oxidation resistance of the second boundary L2 of the second signal line 5, better improving the display effect of the display device.

Optionally, based on the previous embodiments, referring to FIG. 6, the dams include at least a second dam 32 located on the side of the non-display area NA closer to the display area AA than the first dam 31, the height of the first dam 31 is greater than the height of the second dam 32.

Specifically, this arrangement not only effectively blocks the overflow of the organic layer of the encapsulation layer 4 in the display area AA, but also improves the capability of the outer dam 3a to protect the first signal line 2 and the second signal line 5, better improving the display effect of the display device.

Optionally, based on the previous embodiments, the array substrate may also include at least one multiplexer located in the non-display area. The at least one multiplexer is connected to the at least one first signal line. Each multiplexer is configured to convert at least two first signal lines located in the display area into a single first signal line located in the non-display area.

Specifically, this arrangement can reduce the number of first signal lines in the non-display area, reducing the impact of the first signal lines on the touch lines of the touch layer.

Preferably, based on the previous embodiments, the port number ratio of the multiplexer includes 1:9 or 1:12.

Specifically, this arrangement can convert multiple first signal lines in the display area into a single first signal line by using a multiplexer, reducing the number of first signal lines in the non-display area, decreasing the impact of the first signal lines on the touch lines of the touch layer, and better improving the display effect of the display device.

FIG. 7 is another section view taken along direction AA′ of the array substrate of FIG. 1 according to embodiments of the present disclosure. Based on the previous embodiments, referring to FIG. 7, the array substrate may include a first conductive layer M1 disposed on one side of the substrate 1 and a second conductive layer M2 disposed on the side of the first conductive layer M1 away from the substrate 1. The first signal lines 2=located in the first conductive layer M1 are staggered with the first signal lines 2 located in the second conductive layer M2.

Specifically, this arrangement can better reduce the space occupied by the first signal line 2, making wiring more convenient. This arrangement can also reduce mutual interference between adjacent first signal lines 2, better improving the display effect of the display device.

Optionally, based on the previous embodiments, referring to FIG. 7, the array substrate may also include a third conductive layer M3 disposed on the side of the second conductive layer M2 away from the substrate 1. The at least one dam 3 is disposed between the third conductive layer M3 and the encapsulation layer 4, and the second signal line 5 is located in the third conductive layer M3.

Specifically, static electricity caused by bending or stress concentration of the array substrate accumulates; therefore, the third conductive layer M3 is disposed between the second conductive layer M2 and the at least one dam 3, and an insulating layer may be disposed between the third conductive layer M3 and the second conductive layer M2. This arrangement ensures that the second signal line 5 in the third conductive layer M3 is located on the side of the first signal line 2 away from the substrate 1, better improving the capability of the second signal line 5 to shield against static electricity for the first signal line 2, improving the anti-static capability of the array substrate, and improving the service life of the display device.

Optionally, based on the previous embodiments, referring to FIG. 7, the first dam 31 is located on the side of the non-display area NA facing away from the display area AA, the distance range from the first dam 31 to a fourth boundary L4 of the encapsulation layer 4 includes 5 μm to 10 μm.

Specifically, this arrangement increases the distance between the first signal line 2 and the fourth boundary L4 of the encapsulation layer 4, better enhancing the coverage effect of the encapsulation layer 4 on the first signal line 2 and better improving the display effect of the display device.

In an optional embodiment, the distance from the dam 3 to the fourth boundary L4 may be set to a constant value, for example, 6 μm or 7 μm. Optionally, the direction of the fourth boundary L4 of the encapsulation layer 4 may follow the direction of the dam 3 located on the side of the non-display area NA away from the display area AA.

Optionally, based on the previous embodiments, referring to FIG. 7, the encapsulation layer 4 disposed in the non-display area NA includes a first layer CVD1 and a second layer CVD2 which are stacked. Preferably, each of the first layer CVD1 and the second layer CVD2 includes an inorganic material.

Specifically, the encapsulation layer 4 includes a first layer CVD1 and a second layer CVD2 which are stacked, making thicker the encapsulation layer 4 in the display area AA, increasing the flatness of the side of the encapsulation layer 4 away from the substrate 1, better reducing the impact of pits formed by the first signal lines 2 (located in a staggered manner in different layers) on the yield of the touch lines TP of the touch layer disposed on the side of the encapsulation layer 4 away from the substrate 1, and better improving the display effect of the display device.

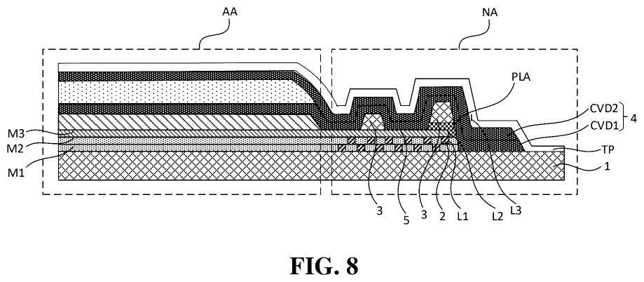

FIG. 8 is another section view taken along direction AA′ of the array substrate of FIG. 1 according to embodiments of the present disclosure. Based on the previous embodiments, referring to FIG. 8, the array substrate may also include a touch line TP located on the side of the encapsulation layer 4 away from the substrate 1 and configured to transmit a touch signal.

Specifically, the touch line TP is configured to transmit a touch signal. The touch line TP is configured on the side of the encapsulation layer 4 away from the substrate 1, producing a better touch effect, better reducing the thickness of the array substrate, and reducing the costs of the array substrate.

An embodiment provides a display device. The display device includes the array substrate of any previous embodiment. The display device has the beneficial effects of the array substrate of any previous embodiment. The details are not described again here.

It is to be noted that the preceding are preferred embodiments of the present disclosure and technical principles used therein. It is to be understood by those skilled in the art that the present disclosure is not limited to the embodiments described herein. For those skilled in the art, various apparent modifications, adaptations and substitutions can be made without departing from the scope of the present disclosure. Therefore, although the present disclosure has been described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. An array substrate, comprising a display area and a non-display area at least partially surrounding the display area, wherein the array substrate comprises:
a substrate;
at least one first signal line disposed on one side of the substrate, and at least part of first signal lines being located in a curved area of the non-display area;
at least one dam disposed in the non-display area and on a side of the at least one first signal line away from the substrate; and
an encapsulation layer disposed on a side of the at least one dam away from the substrate, an orthographic projection of the encapsulation layer on the substrate covers an orthographic projection of the first signal line on the substrate.

2. The array substrate of claim 1, wherein the at least one dam comprises at least a first dam located on a side of the non-display area away from the display area.

3. The array substrate of claim 2, wherein an orthographic projection of the first dam on the substrate, at least partially covers the orthographic projection of the first signal line on the substrate.

4. The array substrate of claim 2, wherein the first signal line has a first boundary away from the display area, the orthographic projection of the first dam on the substrate, covers an orthographic projection of the first boundary on the substrate.

5. The array substrate of claim 2, further comprising:
a second signal line located on the side of the at least one first signal line away from the substrate;
wherein an orthographic projection of the second signal line on the substrate at least partially covers the orthographic projection of the first signal line on the substrate; and
the second signal line is configured to transmit a fixed potential.

6. The array substrate of claim 5, wherein
an orthographic projection of the first dam on the substrate, at least partially covers the orthographic projection of the second signal line on the substrate.

7. The array substrate of claim 5, wherein the second signal line has a second boundary away from the display area, the orthographic projection of the first dam on the substrate, completely covers an orthographic projection of the second boundary on the substrate.

8. The array substrate of claim 7, wherein a distance between the second boundary and a third boundary of the first dam, is greater than or equal to 5 μm.

9. The array substrate of claim 5, wherein the first dam comprises a first insulating layer located on a side of the second signal line away from the substrate,
the first insulating layer covers at least a second boundary of the second signal line away from the display area.

10. The array substrate of claim 9, wherein the first insulating layer comprises an organic material, the at least one dam comprises a second dam located on a side of the non-display area closer to the display area than the first dam, and a height of the first dam is greater than a height of the second dam.

11. The array substrate of claim 1, further comprising:
at least one multiplexer, located in the non-display area, wherein the at least one multiplexer is connected to the at least one first signal line;
the at least one multiplexer is configured to convert at least two first signal lines located in the display area into a single first signal line in the non-display area.

12. The array substrate of claim 11, wherein a port number ratio of the at least one multiplexer comprises 1:9 or 1:12.

13. The array substrate of claim 5, further comprising:
a first conductive layer disposed on one side of the substrate;
a second conductive layer disposed on a side of the first conductive layer away from the substrate, wherein the first signal lines located in the first conductive layer are staggered with first signal lines located in second conductive layer.

14. The array substrate of claim 13, further comprising:
a third conductive layer disposed on a side of the second conductive layer away from the substrate, wherein the at least one dam is disposed between the third conductive layer and the encapsulation layer, and the second signal line is located in the third conductive layer.

15. The array substrate of claim 2, wherein
a distance range from the first dam to a fourth boundary of the encapsulation layer comprises 5 μm to 10 μm.

16. The array substrate of claim 15, wherein the encapsulation layer located in the non-display area comprises a first layer and a second layer which are stacked and respectively comprise an inorganic material.

17. The array substrate of claim 1, further comprising:
a touch line located on a side of the encapsulation layer away from the substrate, wherein the touch line is configured to transmit a touch signal.

18. A display device, comprising the array substrate of claim 1.
